(19) United States
(12) Patent Application Publication
(10) Pub. No.: US 2014/0102515 A1
(43) Pub. Date: Apr. 17, 2014

(54) SOLAR MODULE

(71) Applicant: Sanyo Electric Co., Ltd., Osaka (JP)

(72) Inventors: Toshiyuki Sakuma, Osaka (JP); Tasuku Ishiguro, Kobe-shi (JP)

(73) Assignee: Sanyo Electric Co., Ltd., Osaka (JP)

(21) Appl. No.: 14/132,304

(22) Filed: Dec. 18, 2013

Related U.S. Application Data
(63) Continuation of application No. PCT/JP2012/056857, filed on Mar. 16, 2012.

(30) Foreign Application Priority Data
Jun. 23, 2011 (JP) 2011-139343

(51) Int. Cl. H01L 31/052

(52) U.S. Cl. CPC H01L 31/0525
USPC 136/246

(57) ABSTRACT

A solar module with improved output characteristics is provided. Between adjacent solar cells (10), a first busbar portion (13b) of one solar cell (10) faces a second busbar portion (14b) of the other solar cell (10). The solar module (1) is also provided with a light-reflecting surface (21) arranged in a region between the one solar cell (10) and the other solar cell (10). The light-reflecting surface (21) reflects more of the light incident on the region from the first protecting member (16) towards the one solar cell (10) than towards the other solar cell (10).

### CROSS-REFERENCE TO RELATED APPLICATIONS

This is a continuation of International Application PCT/JP2012/056857, with an international filing date of Mar. 16, 2012, filed by applicant, the disclosure of which is hereby incorporated by reference in its entirety.

### FIELD OF THE INVENTION

The present invention relates to a solar module having a plurality of solar cells.

### BACKGROUND

Solar modules including a plurality of back contact solar cells are conventionally known (see, for example, Patent Document 1). A back contact solar cell does not require the provision of an electrode on the light-receiving surface. In this way, solar modules provided with back contact solar cells have been able to realize improved output characteristics.

### CITED DOCUMENTS

### Patent Documents

Patent Document 1: Laid-Open Patent Publication No. 2005-191479

### SUMMARY

### Problem Solved by the Invention

However, even better output characteristics are desired of solar modules.

It is an object of the present invention to provide a solar module with improved output characteristics.

### Means of Solving the Problem

The solar module of the present invention includes a plurality of solar cells and a transparent first protecting member. Each solar cell has on its back surface a first electrode for collecting a minority carrier and a second electrode for collecting a majority carrier. The first protecting member is arranged on the light-receiving surface side of the plurality of solar cells. The first electrode has a first busbar portion arranged along one side, and a plurality of first finger portions connected electrically to the first busbar portion. The second electrode has a second busbar portion arranged on the other side opposite the one side, and a plurality of finger portions connected electrically to the second busbar portion. Between adjacent solar cells, the first busbar of one solar cell faces the second busbar of the other solar cell. In the solar module of the present invention, a light-reflecting surface is provided in a region between the one solar cell and the other solar cell. The light-reflecting surface reflects more of the light incident on the region from the first protecting member towards the one solar cell than towards the other solar cell.

### Effect of the Invention

The present invention is able to provide a solar module with improved output characteristics.

### BRIEF DESCRIPTION OF THE DRAWINGS

FIG. 1 is a simplified cross-sectional view of the solar module in a first embodiment.

FIG. 2 is an enlarged simplified cross-sectional view of portion II in FIG. 1.

FIG. 3 is a partial simplified plan view of a plurality of solar cells included in the solar module of the first embodiment.

FIG. 4 is a diagram used to explain the effect of the solar module in the first embodiment.

FIG. 5 is a simplified cross-sectional view of the wiring member in the first embodiment.

FIG. 6 is a simplified cross-sectional view of the wiring member in a second embodiment.

FIG. 7 is a simplified cross-sectional view used to explain the light-reflecting surface in a third embodiment.

FIG. 8 is a simplified cross-sectional view used to explain the light-reflecting surface in a fourth embodiment.

### DETAILED DESCRIPTION

The following is an explanation of examples of preferred embodiments of the present invention. The following embodiments are merely examples. The present invention is not limited to the following embodiments in any way.

Further, in each of the drawings referenced in the embodiments, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

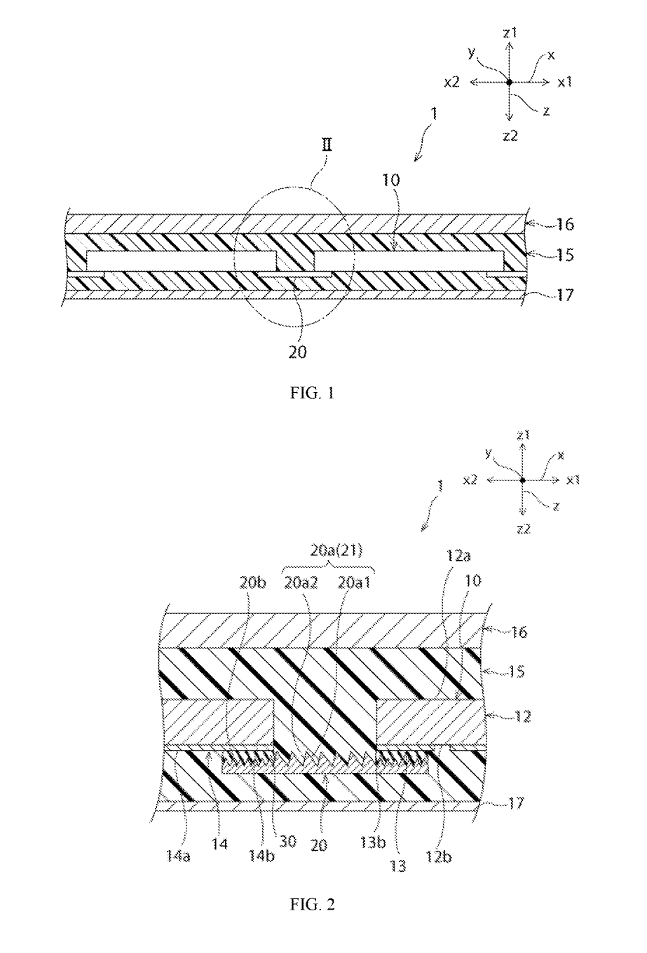

As shown in FIG. 1, the solar module 1 in the present embodiment includes a first protecting member 16, a second protecting member 17, and a plurality of solar cells 10 sealed inside a sealing member 15 between the first protecting member 16 and the second protecting member 17.

The first protecting member 16 has transparent properties and protects the light-receiving surface of the solar cell 10. The first protecting member 16 can be a transparent plate such as a glass plate or plastic plate. At least a portion of the light incident on the solar module 1 passes through the first protecting member 16 and is incident on the light-receiving surface of the solar cell 10.

The second protecting member 17 protects the back surface of the solar cell 10. The second protecting member 17 can be a weather-resistant member such as a weather-resistant resin film or a stacked film in which metal foil is interposed between a pair of resin films.

The sealing member 15 can be made of a resin material such as an ethylene-vinyl acetate (EVA) copolymer, polyvinylbutyral (PVB), polyethylene (PE), and polyurethane (PU).

The solar module 1 may have a terminal box on the surface of the second protecting member 17 to draw on the power generated by the solar cells 10. The module may also have a metal or resin frame on the peripheral edges.

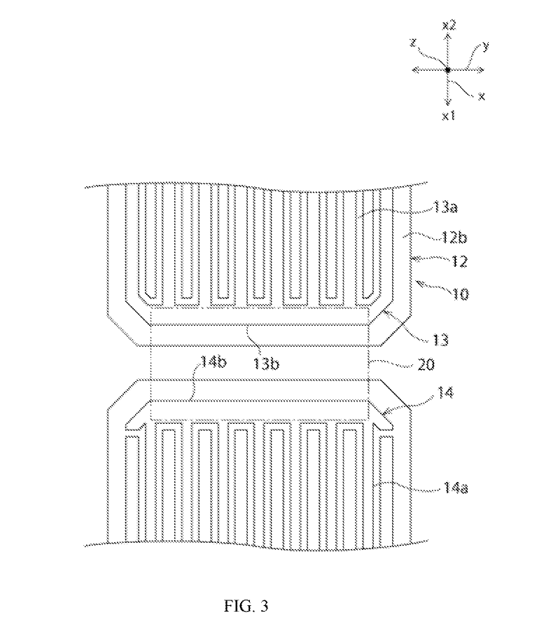

The solar cells 10 are back contact solar cells. Each solar cell 10 has a photoelectric conversion unit 12 (see FIG. 2 and FIG. 3). Each photoelectric conversion unit 12 has a light-receiving surface 12a and a back surface 12b, and has an electrode on the back surface 12b. The configuration of the electrodes is described below.

The light-receiving surface 12a is the main surface receiving light, and is arranged on the side with the first protecting member 16. The photoelectric conversion unit 12 generates carriers from the light received on the light-receiving surface 12a. The solar cell 10 may have a passivation layer or anti-reflecting layer on the light-receiving surface 12a.

There are no particular restrictions on the photoelectric conversion unit 12 as long as the back surface 12b has a p-type surface and n-type surface (not shown). The photoelectric conversion unit 12 may have a substrate made of a semiconductor material of one type of conductivity, and a p-type semiconductor layer and n-type semiconductor layer arranged on the back surface of the substrate. In this case, a substantially intrinsic i-type semiconductor layer of a thickness not contributing substantially to power generation may be arranged between the p-type semiconductor layer and the n-type semiconductor layer. In the photoelectric conversion unit 12, a p-type dopant diffusion region and an n-type dopant diffusion region may be formed on the back surface of the substrate made of a semiconductor material.

A first electrode 13 and a second electrode 14 are arranged on the back surface 12b of the photoelectric conversion unit 12. One of the first electrode 13 and the second electrode 14 is arranged on the p-type surface, and the other is arranged on the n-type surface. The first electrode 13 is the electrode for collecting the minority carrier, and the second electrode 14 is the electrode for collecting the majority carrier. For example, when the photoelectric conversion unit 12 includes a substrate made of an n-type semiconductor material, the first electrode 13 is the p-side electrode, and the second electrode 14 is the n-side electrode.

The first electrode 13 has a plurality of first finger portions 13a and a first busbar portion 13b. The first busbar portion 13b is arranged so as to extend in the y-direction (a first direction) along a side of a photoelectric conversion unit 12 with a substantially rectangular shape. As shown in FIG. 3, the shape of the photoelectric conversion unit 12 may be substantially square, and the four corners may be cut. Each of the plurality of first finger portions 13a extends linearly in the x-direction (a second direction) perpendicular to the y-direction, and the first finger portions 13a are arranged at intervals in the y-direction. The first busbar portion 13b is connected electrically to the plurality of first finger portions 13a. The first busbar portion 13b collects the minority carriers collected by each of the first finger portions 13a. As a result, the width of the first busbar portion 13b is greater than the width of the first finger portions 13a, and resistance loss in the first busbar portion 13b is suppressed.

The second electrode 14 has a plurality of second finger portions 14a and a second busbar portion 14b. The second busbar portion 14b is arranged so as to extend in the y-direction along the side of the photoelectric conversion unit 12 opposite the first busbar portion 13b. Each of the plurality of second finger portions 14a extends linearly in the x-direction, and is arranged alternately at intervals in the y-direction and the second finger portions 14a are arranged at intervals in the y-direction. The plurality of first finger portions 13a and the plurality of second finger portions 14a are arranged alternately at intervals in the y-direction. The second busbar portion 14b is connected electrically to the plurality of second finger portions 14a. The second busbar portion 14b collects the majority carriers collected by each of the second finger portions 14a. As a result, the width of the second busbar portion 14b is greater than the width of the second finger portions 14a, and resistance loss in the second busbar portion 14b is suppressed.

The solar cells 10 are connected electrically by a wiring member 20. The wiring member 20 is arranged between adjacent solar cells 10 in the x-direction. Adjacent solar cells 10 are arranged so that the first busbar portion 13b of one solar cell 10 is facing the second busbar portion 14b of the other solar cell 10. The wiring member 20 connects the first busbar portion 13b of the one solar cell 10 to the second busbar portion 14b of the other solar cell 10.

The solar module 1 also includes a light-reflecting surface 21 opposite the first protecting member 16 in the region between solar cells 10 connected by a wiring member 20. The light-reflecting surface 21 is configured from the surface of the wiring member 20. More specifically, a first uneven surface 20a is provided on the surface of the wiring member 20 on the first protecting member 16 side. The first uneven surface 20a includes a central portion between solar cells 10 connected by a wiring member 20. The light-reflecting surface 21 is configured from this first uneven surface 20a.

In the present invention, “uneven surface” means a convex surface, a concave surface or a surface which is both convex and concave.

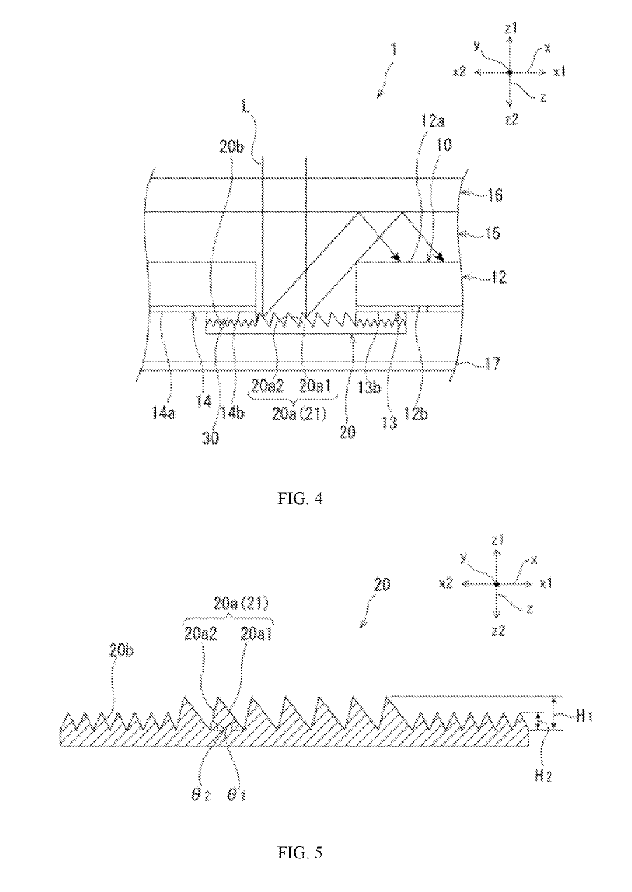

As shown in FIG. 4, the light-reflecting surface 21 composed of the first uneven surface 20a mainly reflects light L passing through the first protecting member 16 and incident on the space between adjacent solar cells 10 towards one of the solar cells 10 (the solar cell 10 on the x1 side of the light-reflecting surface 21 in the x-direction). In other words, the light-reflecting surface 21 is provided between adjacent solar cells 10 so that more of the light reflected by the light-reflecting surface 21 is directed towards one solar cell 10 rather than towards the other solar cell (the one on the x2 side of the light-reflecting surface 21). Most of the light reflected by the light-reflecting surface 21 is reflected at the interface between the sealing member 15 and the first protecting member 16, and at the interface between the first protecting member 16 and the air, after which it is incident on the light-receiving surface 12a of the one solar cell 10. FIG. 4 only shows the optical path of the light reflected at the interface between the sealing member 15 and the first protecting member 16.

More specifically, as shown in FIG. 5, the first uneven surface 20a constituting the light-reflecting surface 21 includes a first inclined surface portion 20a1 whose normal line faces the one solar cell 10, and a second inclined surface portion 20a2 whose normal line faces the other solar cell 10. The first uneven surface 20a is configured so that, in plain view (that is, when viewed from the z-direction), the area occupied by the first inclined surface portion 20a1 is greater than the area occupied by the second inclined surface portion 20a2. In other words, the base angle θ₁ of the first inclined surface portion 20a1 is smaller than the base angle θ₂ of the second inclined surface portion 20a2 (θ₂>θ₁). The height, base angle θ₁ and number of the first inclined surface portions 20a1 and the second inclined surface portions 20a2 are established as appropriate so that most of the light reflected by the light-reflecting surface 21 towards one of the solar cells 10 reaches the first protecting member 16 without being blocked by the solar cell 10.

The wiring member 20 has both a first uneven surface 20a and a second uneven surface 20b on the surface facing the solar cells 10. The second uneven surface 20b is arranged facing the back surface of the solar cells 10. The second uneven surface 20b is bonded to the solar cells 10 using an adhesive layer 30. Because the surface of the wiring member 20 bonded to the solar cells 10 has a second uneven surface 20b, the bonding area can be increased and the bonding strength of the wiring member 20 to the solar cells 10 can be improved. In the present embodiment, the bonding region of the solar cells 10 and the wiring member 20 is formed from the second uneven surface 20b, but this region may be a flat surface instead of an uneven surface.

The second uneven surface 20b and the first uneven surface 20a may have the same shape or different shapes. In the present embodiment, the two inclined surfaces 20a1 and 20a2 of each convex portion constituting the first uneven surface 20a have different base angles. However, the two inclined surfaces of each convex portion constituting the second uneven surface 20b have substantially equal base angles. Also, the height H1 of the unevenness of the first uneven surface 20a (see FIG. 5) is greater than the height H2 of the unevenness of the second uneven surface 20b. The shapes of the second uneven surface 20b and the first uneven surface 20a can be established as appropriate according to function.

However, in order to improve the characteristics of the solar cells, it is important to increase the collection efficiency for the minority carriers generated by the photoelectric conversion unit 12. However, in a back contact solar cell 10, the minority carriers generated in the portion of the photoelectric conversion unit 12 in which the second busbar portion 14b for collecting majority carriers is arranged have to travel a great distance to be collected by the first electrode 13 (first finger portions 13a). Therefore, the minority carriers generated in the portion of the photoelectric conversion unit 12 in which the second busbar portion 14b for collecting minority carriers is arranged are more likely to recombine with the majority carriers and disappear before reaching the first electrode 13.

Therefore, even when the light incident on the region between adjacent solar cells 10 is reflected evenly by the light-reflecting surface 21 towards both solar cells 10, the solar cells 10 provided with first busbar portions 13b and solar cells 10 provided with second busbar portions 14b do not contribute evenly to the generation of power from light incident on their respective light-receiving surfaces 12a. In other words, the light incident on the light-receiving surface 12a of solar cells provided with a second busbar portion 14b on the side with the light-reflecting surface 21 cannot contribute as effectively to the generation of electricity as solar cells 10 provided with a first busbar portion 13b on the side with the light-reflecting surface 21.

Therefore, a light-reflecting surface 21 is provided in the solar module 1 which reflects more of the light L incident on the light-reflecting surface 21 of the wiring member 20 towards the solar cell 10 connected to the first busbar portion 13b for collecting the minority carrier. As a result, the light incident again on the solar cell 10 can be more effectively utilized, and improved output characteristics can be realized.

Also, the wiring member 20 is configured from the light-reflecting surface 21. As a result, a separate member constituting the light-reflecting surface 21 is not required. This reduces the number of components required in the manufacture of solar modules 1, simplifies the manufacturing process, and reduces the cost of solar modules 1.

Because the wiring member 20 is secured to the solar cells 10 using a bonding layer 30, a light-reflecting surface 21 made of the wiring member 20 allows the positional precision of the light-reflecting surface 21 can be easily improved.

The following is an explanation of other examples of a preferred embodiment of the present invention. In the following explanations, all members having functions substantially identical to those in the first embodiment are denoted by the same reference symbols and further explanation of these members has been omitted.

### 2nd Embodiment

FIG. 6 is a simplified cross-sectional view of the wiring member 22 in another embodiment.

The light-incident surface 23 of the wiring member 22 is composed of one convex portion having a first uneven surface 22a with one first inclined surface portion 22a1 and one second inclined surface portion 22a2. The light-reflecting surface 23 is composed of the wiring member 22. The second uneven surface 22b has the same configuration as the second uneven surface 20b in the first embodiment.

### 3rd Embodiment

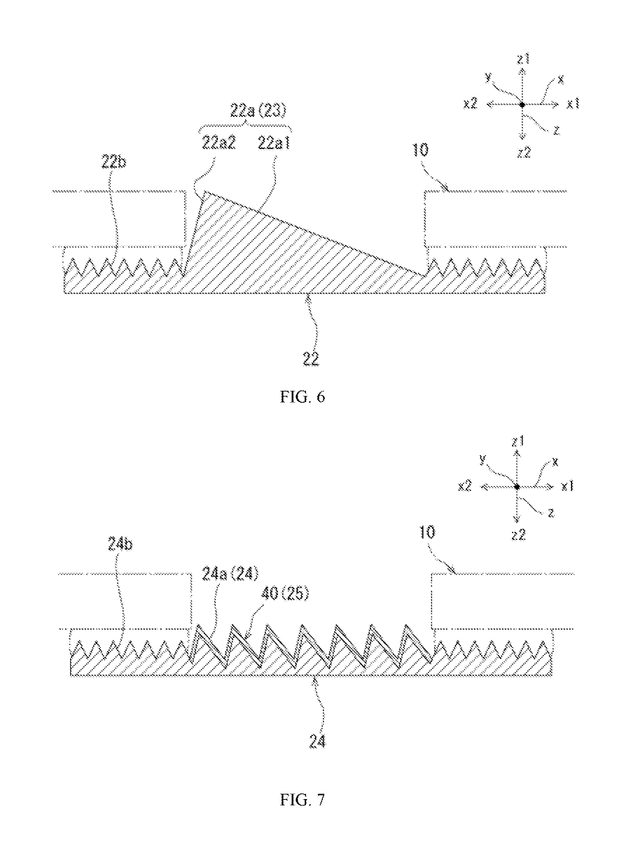

FIG. 7 is a simplified cross-sectional view used to explain the light-reflecting surface 25 in a third embodiment. In the explanations of the first and second embodiments, the light-receiving surface was composed of the wiring member. However, the light-reflecting surface may be composed of a member other than the wiring member. In the present embodiment, a reflecting member 40 provided on the first uneven surface 24a of the wiring member 24 constitutes the light-reflecting surface 25.

Here, the reflecting member 40 is arranged on the wiring member 24. As a result, the reflecting member 40 can be positioned using the wiring member 24 secured to the solar cells 10. This allows the light-reflecting surface 25 to be arranged more easily and with greater precision.

The reflecting member 40 may have conductive or insulating properties, but the reflecting member 40 preferably has a surface with insulating properties. In this way, short-circuiting does not occur when the reflecting member 40 comes into contact with the photoelectric conversion unit 12. As a result, output characteristics do not decline when the reflecting member 40 comes into contact with the photoelectric conversion unit 12.

When the reflecting member 40 has a surface with insulating properties, the reflecting member 40 can be made of an insulating material such as a white resin. The reflecting member 40 can also be a metal member coated with an insulating film. When the reflecting member 40 has a surface with conductive properties, the reflecting member 40 can be made of a metal such as silver or aluminum. The second uneven surface 24b has the same configuration as the second uneven surface 20b in the first embodiment.

### 4th Embodiment

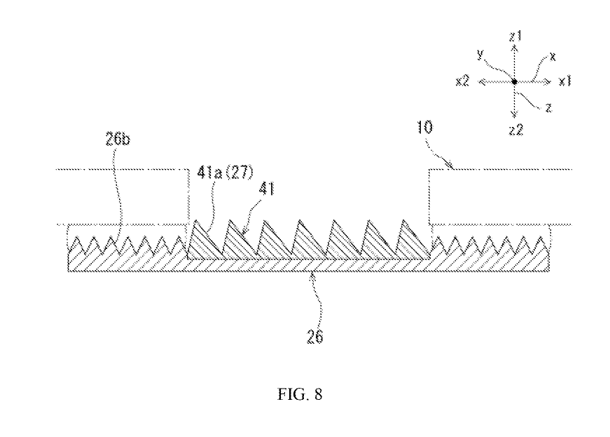

FIG. 8 is a simplified cross-sectional view used to explain the light-reflecting surface 27 in a fourth embodiment. As shown in the drawing, the reflecting member 41 arranged on the wiring member 26 has an uneven surface 41a, and the light-reflecting surface 27 is composed of this uneven surface 41a. The second uneven surface 26b has the same configuration as the second uneven surface 20b in the first embodiment.

The present invention includes many other embodiments not described herein. For example, the light-reflecting member may be arranged in isolation from the wiring member. Therefore, the technical scope of the present invention is defined solely by the items of the invention specified in the claims pertinent to the above explanation.

### KEY TO THE DRAWINGS

1: Solar module

10: Solar cell

12: Photoelectric conversion unit

12a: Light-receiving surface

12b: Back surface

13: First electrode

13a: First finger portion

13b: First busbar portion

14: Second electrode

14a: Second finger portion

14b: Second busbar portion

15: Sealing member

20, 22, 24, 26: Wiring members

20a, 22a: First uneven surfaces

20a1, 22a1: First inclined surface portions

20a2, 22a2: Second inclined surface portions

20b: Second uneven surface

21, 23, 25, 27: Light-reflecting surfaces

30: Adhesive layer

40, 41: Reflecting members

What is claimed is:

1. A solar module comprising:
a plurality of solar cells having on the back surface a first electrode for collecting a minority carrier and a second electrode for collecting a majority carrier; and
a transparent first protecting member arranged on the light-receiving surface side of the plurality of solar cells;
the first electrode having a first busbar portion arranged along one side, and a plurality of first finger portions connected electrically to the first busbar portion;
the second electrode having a second busbar portion arranged on the other side opposite the one side, and a plurality of finger portions connected electrically to the second busbar portion;
between adjacent solar cells, the first busbar of one solar cell facing the second busbar of another adjacent solar cell; and
a light-reflecting surface being provided in a region between the one solar cell and the other solar cell, the light-reflecting surface reflecting more of the light incident on the region from the first protecting member towards the one solar cell than to the other solar cell.

2. The solar module according to claim 1 further comprising:
a wiring member for electrically connecting the first busbar portion of the one solar cell to the second busbar portion of the other solar cell;
the wiring member comprising the light-reflecting surface.

3. The solar module according to claim 2, wherein the light-reflecting surface has a first uneven surface on the side of the wiring member facing the first protecting member.

4. The solar module according to claim 2, wherein the wiring member has a second uneven surface on the side connected to the first and second busbar portions.

5. The solar module according to claim 4, wherein the first uneven surface and the second uneven surface have shapes different from each other.

6. The solar module according to claim 1 further comprising:
a wiring member for electrically connecting the first busbar portion of the one solar cell to the second busbar portion of the other solar cell; and
a reflecting member arranged on the first protecting member side of the wiring member;
the reflecting member comprising the light-reflecting surface.

7. The solar module according to claim 6, wherein the light-reflecting member has a surface with insulating properties.
